(19) United States
(12) Patent Application Publication
(10) Pub. No.: US 2024/0063236 A1
(43) Pub. Date: Feb. 22, 2024

(54) SEMICONDUCTOR PACKAGE AND METHOD OF MANUFACTURING THE SEMICONDUCTOR PACKAGE

(71) Applicant: SAMSUNG ELECTRONICS CO., LTD., Suwon-si (KR)

(72) Inventor: Seokhyun LEE, Suwon-si (KR)

(73) Assignee: SAMSUNG ELECTRONICS CO., LTD., Suwon-si (KR)

(21) Appl. No.: 18/195,618

(22) Filed: May 10, 2023

(30) Foreign Application Priority Data
Aug. 17, 2022 (KR) 10-2022-0102494

(51) Int. Cl. H01L 27/146

(52) U.S. Cl. CPC H01L 27/14618; H01L 27/14689; H01L 27/14636; H01L 27/14643; H01L 27/14627

(57) ABSTRACT

A method of manufacturing a semiconductor package includes forming a first redistribution layer having an opening on a transparent plate, the first redistribution layer including first redistribution wirings; forming a plurality of conductive structures that extend in a vertical direction on the first redistribution layer and are electrically connected to the first redistribution wirings; providing an image sensor chip comprising a lens, and providing a plurality of conductive members; disposing the image sensor chip on the first redistribution layer such that the lens faces the opening and the conductive members are electrically connected to the first redistribution wirings; forming an adhesive member that extends along the peripheral region and surrounds the conductive members; forming a sealing member on the first redistribution layer to cover the image sensor chip, the conductive structures, and the adhesive member; and forming a second redistribution layer.

### CROSS-REFERENCE TO RELATED APPLICATION

This application claims priority to Korean Patent Application No. 10-2022-0102494, filed on Aug. 17, 2022, in the Korean Intellectual Property Office, the contents of which are incorporated by reference herein in its entirety.

### BACKGROUND

### 1. Field

Example embodiments relate to a semiconductor package and a method of manufacturing the semiconductor package. More particularly, example embodiments relate to a semiconductor package including a CMOS image sensor and a method of manufacturing the same.

### 2. Description of Related Art

In a manufacturing process of a semiconductor device including a CMOS image sensor (CIS) chip, the semiconductor device may be completed through a packaging process after forming through silicon vias (TSV). Since the manufacturing process of the semiconductor device includes a process for forming the through silicon via, the manufacturing process may be complicated and cost may increase. In addition, since the semiconductor device includes the through silicon via, there may also be a problem in that the size of the semiconductor device increases.

### SUMMARY

Example embodiments provide a semiconductor package including a structure capable of reducing manufacturing cost and reducing a size of an image sensor chip and a method of manufacturing the semiconductor package.

According to an aspect of an example embodiment, a semiconductor package, includes: forming a first redistribution layer having an opening on a transparent plate, the first redistribution layer comprising first redistribution wirings; forming a plurality of conductive structures that extend in a vertical direction on the first redistribution layer and are electrically connected to the first redistribution wirings; providing an image sensor chip comprising a lens, and providing a plurality of conductive members spaced apart along a peripheral region of the lens; disposing the image sensor chip on the first redistribution layer such that the lens faces the opening and the conductive members are electrically connected to the first redistribution wirings; forming an adhesive member that extends along the peripheral region and surrounds the conductive members between the first redistribution layer and the image sensor chip; forming a sealing member on the first redistribution layer to cover the image sensor chip, the conductive structures, and the adhesive member; and forming a second redistribution layer comprising second redistribution wirings electrically connected to the conductive structures, on the sealing member.

According to an aspect of an example embodiment, a method of manufacturing a semiconductor package, includes: forming a first redistribution layer having an opening on a transparent plate, the first redistribution layer comprising first redistribution wirings; forming a plurality of conductive structures that extend in a vertical direction on the first redistribution layer and are electrically connected to the first redistribution wirings; providing a CMOS image sensor chip comprising a lens, and providing a plurality of conductive members spaced apart along a peripheral region of the lens; disposing the CMOS image sensor chip on the first redistribution layer such that the lens faces the opening and the conductive members are electrically connected to the first redistribution wirings; forming an adhesive member that extends along the peripheral region between the first redistribution layer and the CMOS image sensor chip to enclose the conductive members and seal a space between the lens and the opening on the transparent plate; forming a sealing member on the first redistribution layer to cover the CMOS image sensor chip, the conductive structures, and the adhesive member; and forming a second redistribution layer that has second redistribution wirings electrically connected to the conductive structures, on the sealing member.

According to an aspect of an example embodiment, a semiconductor package, includes: a transparent plate configured to allow light to transmit therethrough; a first redistribution layer disposed on the transparent plate, the first redistribution layer having an opening through which light may pass, the first redistribution layer comprising first redistribution wirings; an image sensor chip comprising a lens, further comprising a plurality of conductive members in a peripheral region surrounding the lens, and wherein the image sensor chip is disposed on the first redistribution layer such that the conductive members are electrically connected to the first redistribution wirings, the lens facing the opening that such that light may be incident on the lens; an adhesive member extending along the peripheral region between the first redistribution layer and the image sensor chip, the adhesive member surrounding the conductive members to enclose a space between the lens and the opening from an outside; a sealing member provided on the first redistribution layer to cover the image sensor chip and the adhesive member; a second redistribution layer provided on the sealing member, the second redistribution layer having second redistribution wirings; and a plurality of conductive structures penetrating through the sealing member and electrically connecting the first redistribution wirings and the second redistribution wirings.

### BRIEF DESCRIPTION OF DRAWINGS

The above and other aspects and features will be more apparent from the following description of example embodiments, taken in conjunction with the accompanying drawings, in which:

FIG. 1 is a cross-sectional view illustrating a semiconductor package in accordance with example embodiments.

FIG. 2 is a plan view illustrating a semiconductor package in accordance with example embodiments.

FIG. 3 is a cross-sectional view taken the along line A-A′ in FIG. 2.

FIG. 4 is a plan view taken the along line B-B′ in FIG. 3.

FIG. 5 is an enlarged cross-sectional view illustrating portion ‘C’ in FIG. 3.

FIG. 6 is an enlarged cross-sectional view illustrating portion ‘D’ in FIG. 3.

FIGS. 7 to 17 are cross-sectional views illustrating a method of manufacturing a semiconductor package in accordance with example embodiments.

### DETAILED DESCRIPTION OF EXAMPLE EMBODIMENTS

Example embodiments will be described more fully with reference to the accompanying drawings, in which example embodiments are shown. Embodiments described herein are provided as examples, and thus, the present disclosure is not limited thereto, and may be realized in various other forms. Each example embodiment provided in the following description is not excluded from being associated with one or more features of another example or another example embodiment also provided herein or not provided herein but consistent with the present disclosure. It will be understood that when an element or layer is referred to as being “on,” “connected to” or “coupled to” another element or layer, it can be directly on, connected or coupled to the other element or layer, or intervening elements or layers may be present. By contrast, when an element is referred to as being “directly on,” “directly connected to” or “directly coupled to” another element or layer, there are no intervening elements or layers present. Expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

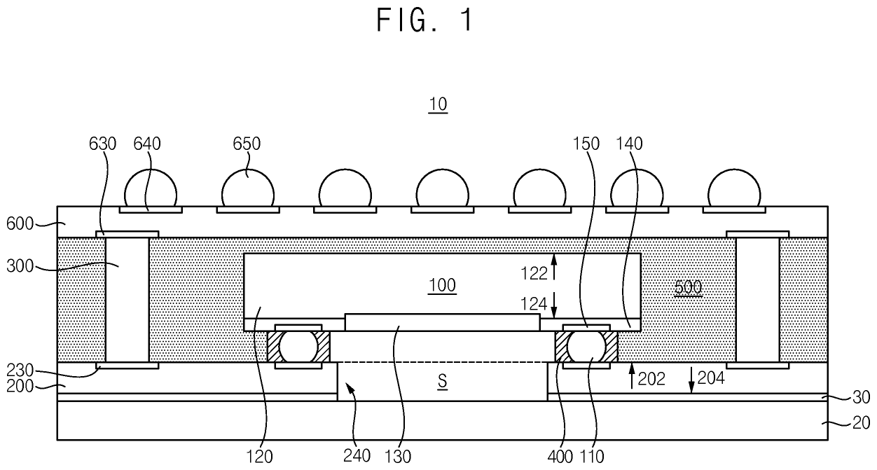

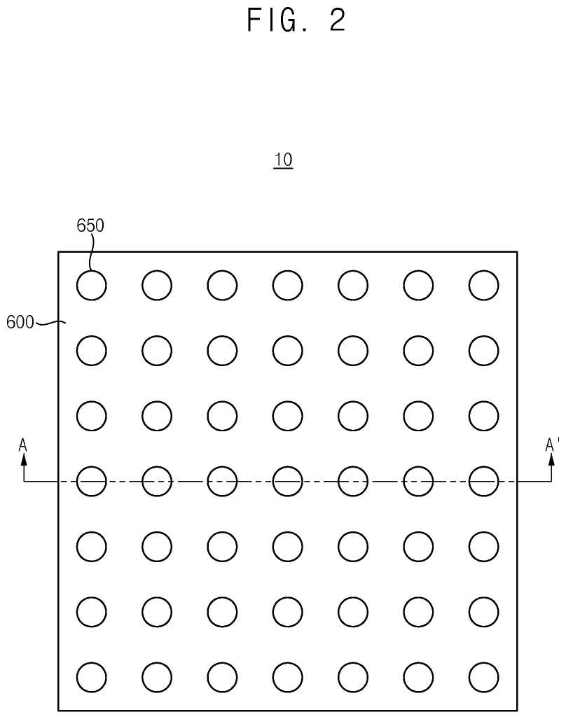

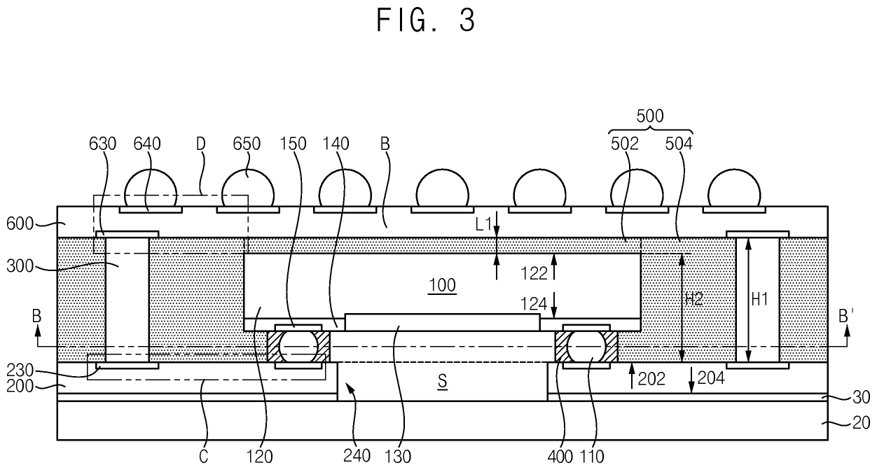

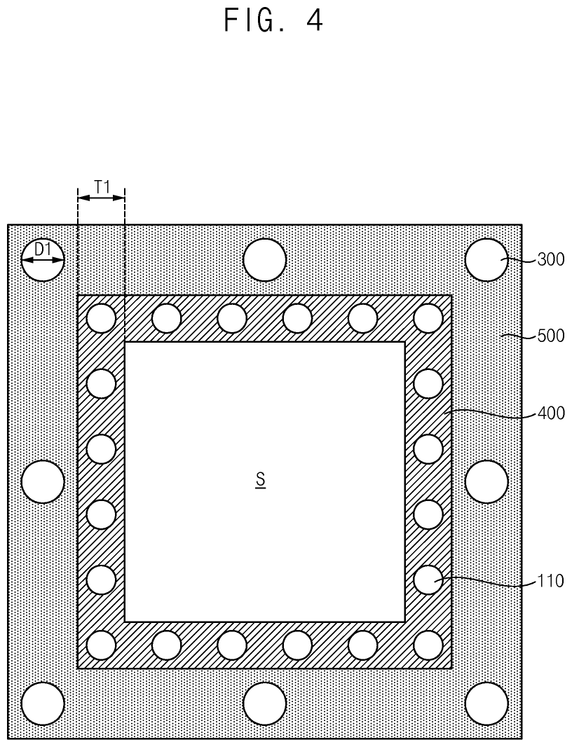

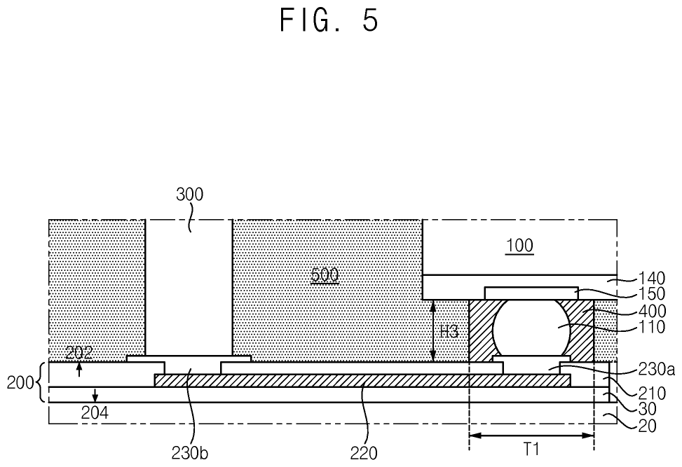

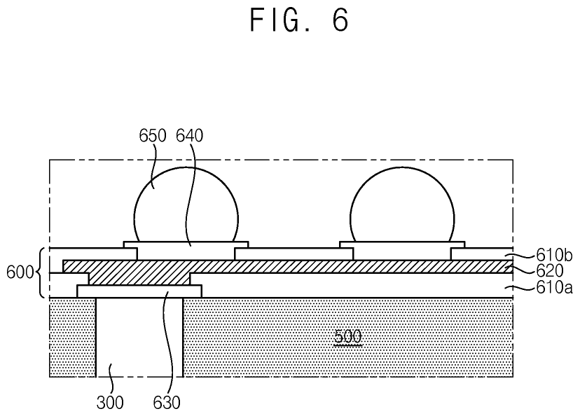

FIG. 1 is a cross-sectional view illustrating a semiconductor package in accordance with example embodiments. FIG. 2 is a plan view illustrating a semiconductor package in accordance with example embodiments. FIG. 3 is a cross-sectional view taken the along line A-A′ in FIG. 2. FIG. 4 is a plan view taken the along line B-B′ in FIG. 3. FIG. 5 is an enlarged cross-sectional view illustrating portion ‘C’ in FIG. 3. FIG. 6 is an enlarged cross-sectional view illustrating portion ‘D’ in FIG. 3.

Referring to FIGS. 1 to 6, the semiconductor package 10 may include transparent plate 20, a first redistribution layer 200 provided on the transparent plate, an image sensor chip 100 disposed on the first redistribution layer 200 through conductive members 110, a plurality of conductive structures 300 provided on the first redistribution layer 200, an adhesive member 400 surrounding the conductive members 110, a sealing member 500 covering the image sensor chip 100, and a second redistribution layer 600 disposed on the sealing member 500. The semiconductor package 10 may further include a spacer layer 30 provided between the transparent plate 20 and the first redistribution layer 200.

In example embodiments, the transparent plate 20 may include a transparent material that transmits light. The transparent plate 20 may pass the light incident from an outside to the image sensor chip 100. The transparent plate 20 may protect the image sensor chip 100 from external impact. For example, the transparent plate 20 may include glass, aluminum nitride (AlN), or the like.

In example embodiments, the spacer layer 30 may adhere the first redistribution layer 200 to the transparent plate 20. The spacer layer 30 may include the transparent material. The spacer layer 30 may include a cavity for passing the light passing through the transparent plate 20 to the image sensor chip 100. For example, the spacer layer 30 may include an epoxy resin, silicon oxide, silicon nitride, silicon oxynitride, polyimide, butylcyclobutene parylene, polynaphthalene, fluorocarbon, and acrylate.

In example embodiments, the first redistribution layer 200 may include a first surface 202 and a second surface 204 opposite to each other. The first redistribution layer 200 may be disposed on the transparent plate 20 such that the second surface 204 faces the transparent plate 20. The first redistribution layer 200 may include a central opening 240 for passing the light passing through the transparent plate 20 to the image sensor chip 100. The first redistribution layer 200 may include a plurality of first bonding pads 230 for electrically connecting to the conductive member 110 of the image sensor chip 100 and the conductive structures 300.

The first redistribution layer 200 may include a plurality of first insulating layers 210 and first redistribution wirings 220 provided in the insulating layers 210.

The insulating layers 210 may include, for example, a polymer, a dielectric layer, or the like. The insulating layer may include polyimide (PI), lead oxide (PbO), polyhydroxystyrene (PHS), NOVOLAC, and the like. The insulating layer may be formed by a vapor deposition process, a spin coating process, or the like. The redistribution wiring may include aluminum (Al), copper (Cu), tin (Sn), nickel (Ni), gold (Au), platinum (Pt), or an alloy thereof. The redistribution wiring may be formed by a plating process, an electroless plating process, a vapor deposition process, or the like.

As shown in FIG. 5, the first redistribution wiring 220 may be provided in the first insulating layer 210. The first insulating layer 210 may extend in a longitudinal direction of the first redistribution layer 200 on the transparent plate 20 to electrically connect the first bonding pads 230a, 230b. The first insulating layer 210 may have a first opening exposing an upper surface of the first redistribution wiring 220. The first redistribution wiring 220 may contact the first bonding pads 230a, 230b through the first opening.

The first bonding pad 230 may be formed on the first insulating layer 210 and may contact the first redistribution wiring 220 through the first opening. Accordingly, the first bonding pad 230 may be exposed from an upper surface of the first insulating layer 210. The first bonding pad 230 may include, for example, a metal material such as copper (Cu) or aluminum (Al).

In example embodiments, the conductive structure 300 may penetrate the sealing member 500 and extend vertically through the sealing member 500 to electrically connect the first redistribution layer 200 and the second redistribution layer 600. The conductive structure 300 may be provided on the first redistribution layer 200. The conductive structure 300 may extend vertically from the first redistribution layer 200 in the same vertical direction as a thickness direction of the first redistribution layer 200.

The conductive structure 300 may be electrically connected to the first bonding pad 230 of the first redistribution layer 200. The conductive structure 300 may be electrically connected to the image sensor chip 100 through the first redistribution layer 200. The conductive structure 300 may be electrically connected to a second bonding pad 630 of the second redistribution layer 600. The conductive structure 300 may provide a signal movement path for electrically connecting the first and second redistribution layers 200, 600 and the image sensor chip 100.

Each of the conductive structures 300 may have a first height H1 from the first surface 202 of the first redistribution layer 200. The conductive structures 300 may have a first diameter D1. The first height H1 of the conductive structures 300 may be in a range from about 50 μm to about 300 μm. The first diameter D1 of the conductive structures 300 may be in a range from about 50 μm to about 200 μm.

The conductive structure 300 may, for example, have a pillar shape, a bump shape, or the like. The conductive structure 300 may include at least one of nickel (Ni), antimony (Sb), bismuth (Bi), zinc (Zn), indium (In), palladium (Pd), platinum (Pt), aluminum (Al), copper (Cu), molybdenum (Mo), titanium (Ti), gold (Au), silver (Ag), chromium (Cr), and tin (Sn). The conductive structure 300 may be formed by a plating process, an electroless plating process, a vapor deposition process, or the like.

In example embodiments, the image sensor chip 100 may include a silicon layer 120, an optical component 130 including a lens, an insulating layer 140, a chip pad 150, and a plurality of conductive members 110. The optical component 130 of example embodiments may include a lens as its sole component such that the optical component 130 shown in and described with, for example, FIG. 1, is entirely a lens. That is, in an example embodiment, the optical component 130 may be a lens. In other example embodiments, the optical component 130 may include multiple components and the lens is one part of the optical component.

The image sensor chip 100 may include a complementary metal oxide semiconductor (CMOS) image sensor chip. The CMOS image sensor (CIS) chip may include an active pixel region for capturing an image and a CMOS logic region for controlling an output signal of the active pixel region. The active pixel region may include a photodiode and a MOS transistor, and the CMOS logic region may include a plurality of CMOS transistors.

The image sensor chip 100 may be disposed on the first surface 202 of the first redistribution layer 200. A planar region of the image sensor chip 100 may be smaller than a planar region of the first redistribution layer 200. In a plan view, the image sensor chip 100 may be disposed in a region of the first redistribution layer 200. The image sensor chip 100 may be disposed such that the lens of the optical component 130 faces the central opening 240 of the first redistribution layer 200. For example, in an example embodiment, the lens of the optical component 130 may face downwardly. An upper surface of the image sensor chip 100 may have a second height H2 from the first surface 202 of the first redistribution layer 200. The second height H2 of the upper surface of the image sensor chip 100 may be lower than the first height H1 of the conductive structure 300. The second height H1 of the image sensor chip 100 may be in a range of from about 50 μm to about 200 μm.

The silicon layer 120 may include a silicon substrate, another semiconductor substrate, or the like. The silicon layer 120 may include an upper surface 122 and a lower surface 124 opposite to the upper surface 122. The upper surface 122 may face in an upward direction, for example, towards the second redistribution layer 600. The lower surface 124 may face in a downward direction, opposite the upward direction. An active layer may be provided on the lower surface 124 of the silicon layer 120. The active layer may include, for example, an inter-layer dielectric (ILD) and an inter-metal dielectric (IMD).

The insulating layer 140 may be provided on the lower surface 124 of the silicon layer 120. The insulating layer 140 may be provided on the active layer. The insulating layer 140 may include a passivation layer to cover and protect the active layer. For example, the insulating layer 140 may include silicon oxide, silicon nitride, silicon oxynitride, or metal oxide. The insulating layer 140 may have an opening through which the chip pad 150 is exposed. At least the passivation layer of the insulating layer 140 may have an opening portion for exposing the chip pad 150.

The chip pad 150 may be electrically connected to wirings in the active layer on the lower surface 124 of the silicon layer 120. The chip pad 150 may be exposed through the opening portion to attach the conductive members 110. The chip pad 150 may be electrically connected to the optical component 130. The chip pad 150 may include, for example, a metal material such as copper (Cu) or aluminum (Al).

The conductive members 110 may be provided between the image sensor chip 100 and the first redistribution layer 200. The conductive members 110 may be provided in a peripheral region surrounding a lens of the optical component 130. The conductive members 110 may support and fix the image sensor chip 100 on the first redistribution layer 200. The conductive members 110 may electrically connect the image sensor chip 100 and the first redistribution layer 200. In an example embodiment, there may be a plurality of rows of conductive members 110. The conductive members 110 may be formed around a peripheral region of the optical component 130, such as a peripheral region of a lens of the optical component 130. In various example embodiments, there may be anywhere from, for example, two to eight rows of conductive members 110 may be arranged in the peripheral region.

In an example embodiment, the conductive members 110 may be formed by a plating process. Alternatively or additionally, the conductive members 110 may be formed by a screen printing method, a vapor deposition method, or the like. For example, the conductive members 110 may include C4 bumps.

The optical component 130 may include a lens for acquiring the light. In an example embodiment, the lens may at least one of direct, redirect, focus or allow light to pass through. The optical component 130 may be provided on the lower surface 124 of the silicon layer 120. The lens of the optical component 130 may be provided toward the central opening 240 of the first redistribution layer 200. The optical component 130 may acquire the light incident through the transparent plate 20 and the first redistribution layer 200 through the lens. The optical component 130 may include one or more of a micro lens, a color filter layer, and the like. The optical component 130 may include one or more of a sensing element, a photo sensing element, an optoelectronic element, a temperature sensing element, a capacitive sensing element, and the like.

In example embodiments, the adhesive member 400 may enclose a sealed space S between the lens and the central opening 240 from an outside. The adhesive member 400 may be provided in the peripheral region surrounding the lens of the optical member 130. The adhesive member 400 may be provided to surround each of the conductive members 110.

The adhesive member 400 may be filled to reinforce a gap between the conductive members 110. In an example embodiment, the adhesive member 400 may have a dam shape. The adhesive member 400 may include, for example an epoxy resin, a UV resin, a polyurethane resin, a silicone resin, or a silica filler.

The adhesive member 400 may have a rectangular ring shape having a predetermined gap from an inner surface of the sealing member 500. The adhesive member 400 may have a first width T1 (the predetermined gap) and a third height H3. For example, the first width T1 may be in a range of from about 50 μm to about 200 μm. The third height H3 may be, for example, in a range of from about 15 μm to about 150 μm.

In example embodiments, the sealing member 500 may cover the image sensor chip 100, the adhesive member 400, and the conductive structures 300. The sealing member 500 may be provided on the first redistribution layer 200 to fill a space between the first and second redistribution layers 200, 600. The sealing member 500 may surround the adhesive member 400 such that the sealed space S between the lens and the central opening 240 enclosed by the adhesive member 400 is maintained.

The sealing member 500 may protect the image sensor chip 100, the first redistribution layer 200, and the conductive structure 300 from external environmental contaminants, and the sealing member 500 may improve durability of the semiconductor package 10. The sealing member 500 may provide an electrical connection path between the image sensor chip 100, the first and second redistribution layers 200, 600, and the conductive structure 300.

The sealing member 500 may include a plurality of through openings in which the conductive structure 300 is inserted and through which the conductive structure 300 extends. In the through opening, one end of the conductive structure 300 may be connected to the first bonding pad 230 of the first redistribution layer 200, and the other end of the conductive structure 300 may be connected to the second bonding pad 630 of the second redistribution layer 600.

The second redistribution layer 600 may be disposed on the sealing member 500. The sealing member 500 may have a parallel upper region such that the second redistribution layer 600 is disposed.

The sealing member 500 may cover the upper surface 122 of the image sensor chip 100. The sealing member 500 may include a first sealing portion 502 covering the upper surface 122 of the image sensor chip 100 and a second sealing portion 504 covering an outer surface of the image sensor chip 100. The first sealing portion 502 may be provided between the second redistribution layer 600 and the image sensor chip 100 such that the second redistribution layer 600 and the image sensor chip 100 are spaced apart from each other. The first sealing portion 502 may have a first thickness L1 between the second redistribution layer 600 and the image sensor chip 100. For example, the first thickness L1 of the first sealing portion 502 may be in a range of from about 20 μm to about 200 μm.

In an example embodiment, the sealing member 500 may include an epoxy mold compound (EMC).

In example embodiments, the second redistribution layer 600 may be disposed on the upper surface of the sealing member 500.

The second redistribution layer 600 may include a plurality of the second bonding pads 630 that are electrically connected to the image sensor chip 100 and the first redistribution layer 200. The conductive structure 300 may be provided on the second bonding pad 630.

The second redistribution layer 600 may include a plurality of external connection members 650 for electrical connection with an external device, and a plurality third bonding pads 640 electrically connected to the external connection members 650. The external connection member 650 may be provided on the third bonding pad 640.

The second redistribution layer 600 may include a plurality of insulating layers 610a, 610b and second redistribution wirings 620 provided in the insulating layers.

The insulating layers may include, for example, at least one of a polymer, a dielectric layer, or the like. For example, the insulating layer may include at least one of polyimide (PI), lead oxide (PbO), polyhydroxystyrene (PHS), NOVOLAC, or the like. The insulating layer may be formed by a vapor deposition process, a spin coating process, or the like. The second redistribution wiring may include aluminum (Al), copper (Cu), tin (Sn), nickel (Ni), gold (Au), platinum (Pt), or an alloy thereof. The second redistribution wiring may be formed by a plating process, an electroless plating process, a vapor deposition process, or the like.

In an example embodiment, the plurality of second bonding pads 630 may be provided in the second insulating layer 610a. A lower surface of the second bonding pad 630 may be exposed from the lower surface of the second insulating layer 610a. The second insulating layer 610a may have a second opening exposing a lower surface of the second bonding pad 630.

The second redistribution wiring 620 may be formed on the second insulating layer 610a and may contact the second bonding pad 630 through the second opening. The third bonding pad 640 may be formed on the second insulating layer 610a and may contact the second redistribution wiring 620 through a third opening. Accordingly, the plurality of third bonding pads 640 may be provided to be exposed from an upper surface of the second insulating layer 610a. The external connection member 650 may be provided on the third bonding pad 640. For example, the second and third bonding pads 630, 640 may include a metal material such as copper (Cu) or aluminum (Al).

Hereinafter, a method of manufacturing the semiconductor package of FIG. 1 will be described.

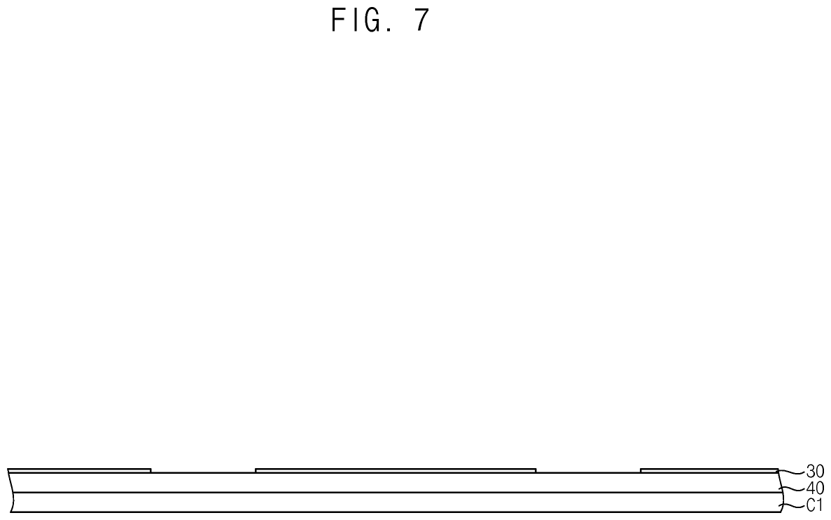

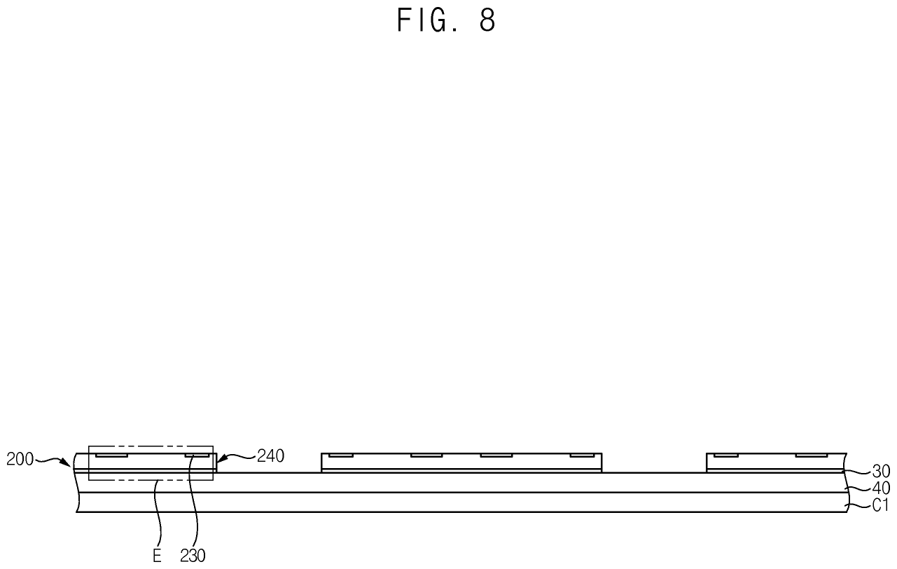

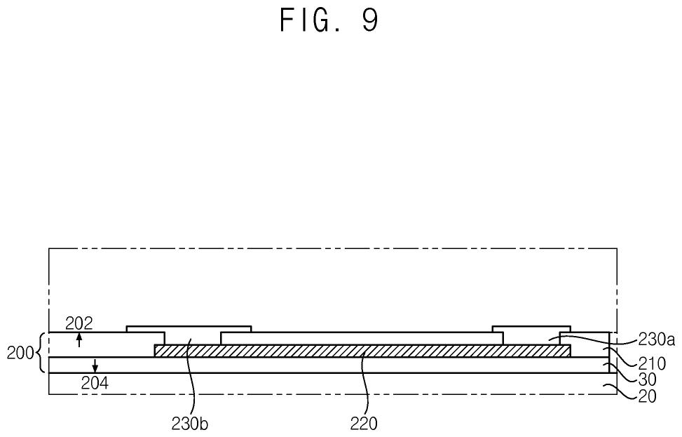

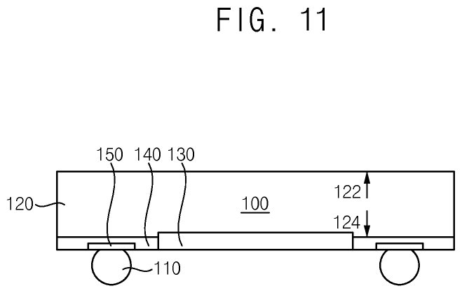

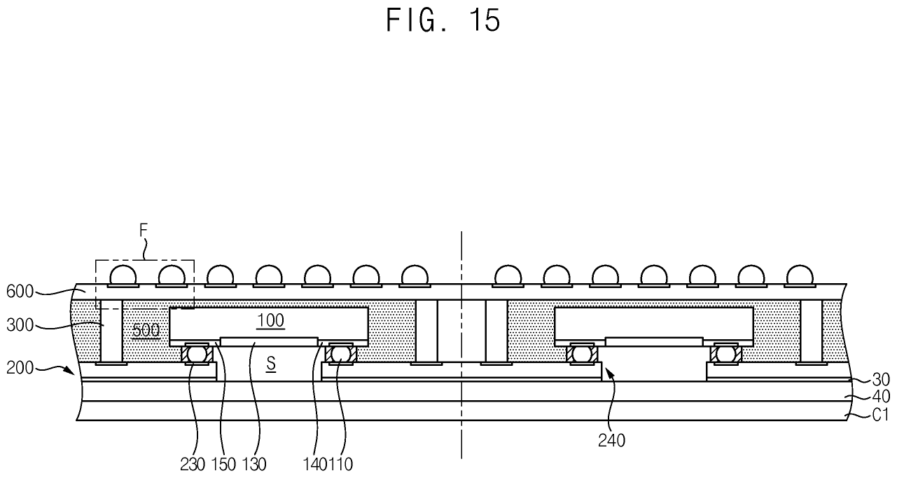

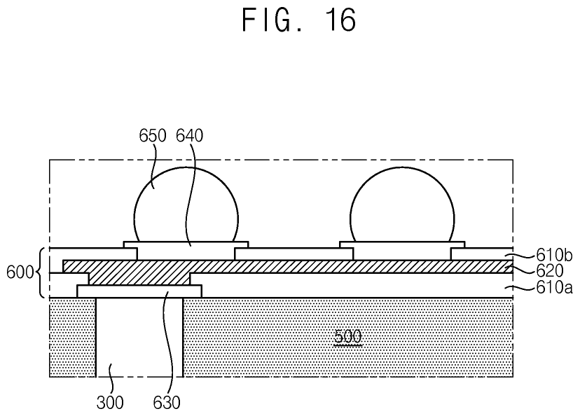

FIGS. 7 to 17 are cross-sectional views illustrating a method of manufacturing a semiconductor package in accordance with example embodiments. FIG. 9 is an enlarged cross-sectional view illustrating portion ‘E’ in FIG. 8. FIG. 11 is a cross-sectional view illustrating an image sensor chip disposed on a second redistribution layer. FIG. 16 is an enlarged cross-sectional view illustrating portion ‘F’ in FIG. 15.

Referring to FIGS. 7 to 9, a first redistribution layer 200 having an opening may be formed on a transparent plate 20.

As illustrated in FIG. 7, a glass 40 including a plurality of the transparent plates 20 may be formed on a carrier substrate Cl. The glass 40 may include a transparent material that transmits light. For example, the glass 40 may include glass, aluminum nitride (AlN), or the like. The glass 40 may have a semiconductor wafer shape.

A spacer layer 30 may be formed on the carrier substrate Cl. The spacer layer 30 may adhere the first redistribution layer 200 to the transparent plate 20. The spacer layer 30 may include a cavity for allowing light that has passed through the transparent plate 20 to reach an image sensor chip 100 (see FIG. 11). For example, the spacer layer 30 may include a transparent material. The spacer layer 30 may be formed through a deposition process. The cavity of the spacer layer 30 may be formed through an exposure process.

As illustrated in FIGS. 8 and 9, a first insulating layer 210 may be formed on the spacer layer 30. A first redistribution wiring 220 may be formed on the first insulating layer 210. A central opening 240 may be formed in a central portion of the first redistribution layer 200 to allow the light to pass therethrough.

In an example embodiment, the first redistribution wiring 220 may be formed in the first insulating layer 210. The first insulating layer 210 may extend in an extending direction of the first redistribution layer 200 on the transparent plate 20 to electrically connect first bonding pads 230a and 230b to each other. A first opening may be formed in the first insulating layer 210 to expose an upper surface of the first redistribution wiring 220 therethrough.

The first redistribution wiring 220 may be formed by forming a seed layer on a portion of the first insulating layer 210, patterning the seed layer, and performing an electrolytic plating process. The first redistribution wiring 220 may be formed to contact the first bonding pads 230a, 230b through the first opening. For example, the first redistribution wiring may include aluminum (Al), copper (Cu), tin (Sn), nickel (Ni), gold (Au), platinum (Pt), or an alloy thereof.

The first bonding pad 230 may be formed on the first insulating layer 210 and may contact the first redistribution wiring 220 through the first opening. Accordingly, the first bonding pad 230 may be exposed from an upper surface of the first insulating layer 210. The first bonding pad 230 may include, for example, a metal material such as copper (Cu) or aluminum (Al).

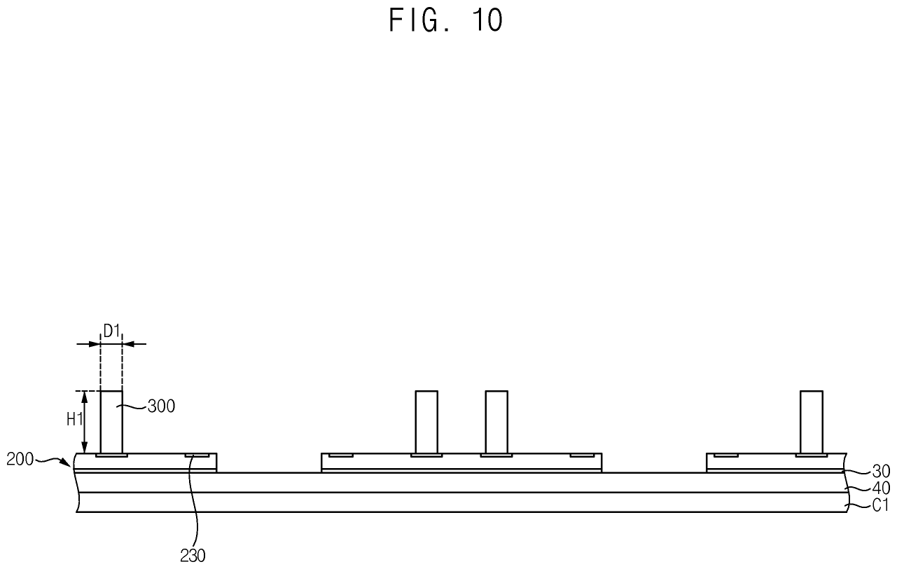

Referring to FIG. 10, a plurality of conductive structures 300 may be formed on the first bonding pads 230 respectively. For example, the conductive structure 300 may include a pillar shape, a bump shape, or the like. For example, the conductive structure 300 may be formed by a plating process, an electroless plating process, a vapor deposition process, or the like.

The conductive structures 300 may be formed to have a first height H1 from an upper surface (a first surface) of the first redistribution layer 200. The conductive structures 300 may be formed to have a first diameter D1. The first height H1 of the conductive structure 300 may be in a range of from about 50 μm to about 300 μm. The first diameter D1 of the conductive structure 300 may be in a range of from about 50 μm to about 200 μm.

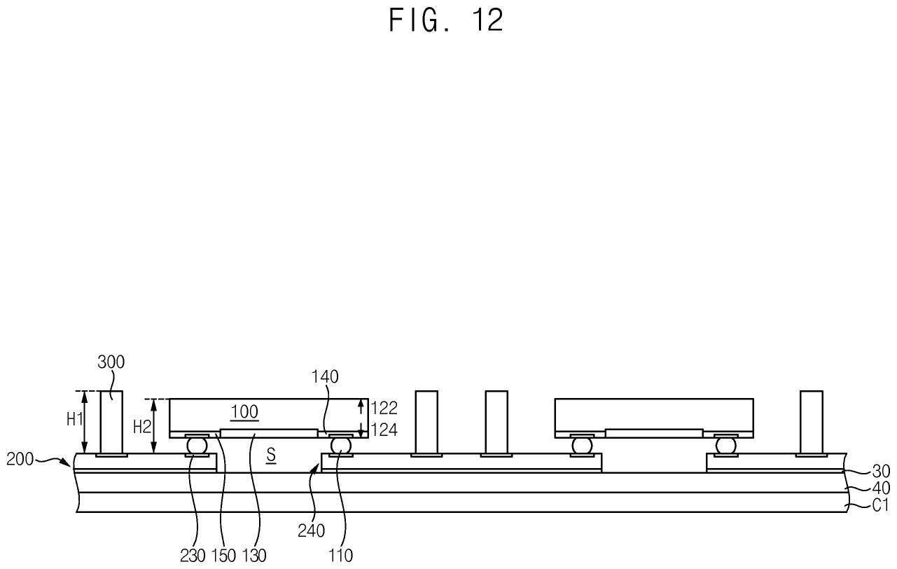

Referring to FIGS. 11 and 12, the image sensor chip 100 having an optical component 130 with a lens and a plurality of conductive members 110 surrounding a peripheral region of the lens may be disposed on the first redistribution layer 200. The image sensor chip 100 may be disposed such that an optical component 130 having the lens faces the central opening 240 and the conductive members 110 are electrically connected to the first redistribution layer 200. For example, the image sensor chip 100 may include a complementary metal oxide semiconductor (CMOS) image sensor chip.

The conductive members 110 may electrically connect the first redistribution layer 200 and the image sensor chip 100. The conductive members 110 may be disposed in the peripheral region surrounding the lens of the optical component 130.

For example, the conductive members 110 may be formed by a plating process. Alternatively, the conductive members 110 may be formed by a screen printing method, a vapor deposition method, or the like. For example, the conductive members 110 may include C4 bumps.

After the conductive members 110 of the image sensor chip 100 are disposed on the first redistribution layer 200, the image sensor chip 100 may be fixedly adhered on the first redistribution layer 200 through a reflow process. The image sensor chip 100 may be adhered to the first redistribution layer 200 by the conductive members 110.

An upper surface 122 of the image sensor chip 100 may be formed to have a second height H2 from the upper surface of the first redistribution layer 200. The second height H2 of the image sensor chip 100 may be lower than the first height H1 of the conductive structure 300.

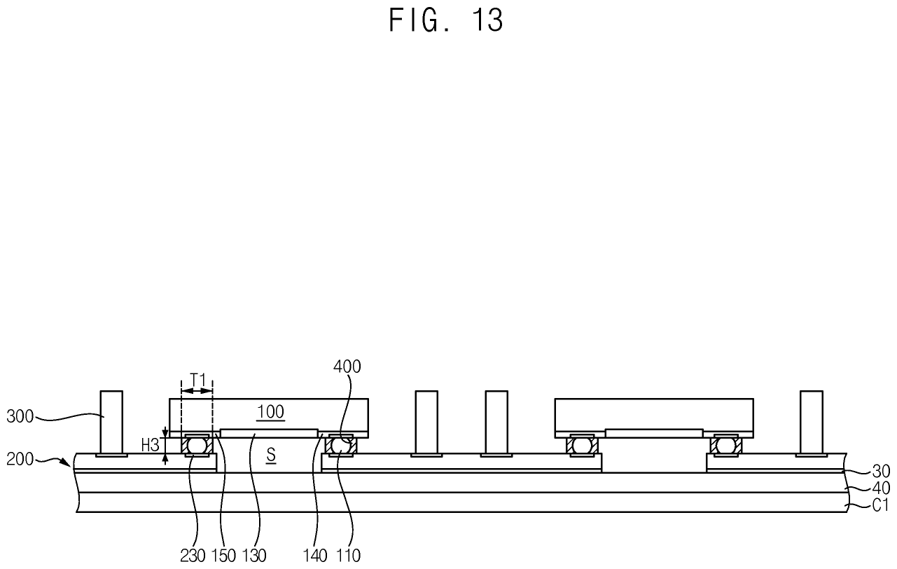

Referring to FIG. 13, an adhesive member 400 may be formed to surround the conductive members 110 in order to enclose a sealed space S between the lens and the opening from an outside between the first redistribution layer 200 and the image sensor chip 100.

The adhesive member 400 may be formed to enclose the sealed space S between the lens and the central opening 240 from the outside. The adhesive member 400 may be formed in the peripheral region surrounding the lens. The adhesive member 400 may be provided to surround each of the conductive members 110. The adhesive member 400 may include a first adhesive portion surrounding the conductive member 110, and a second adhesive portion filling a space between the conductive members 110 and having a dam shape.

The adhesive member 400 may be formed to have a rectangular ring shape having a predetermined gap from an inner surface of a sealing member 500. The adhesive member 400 may have a first width T1 (the predetermined gap) and a third height H3. For example, the first width T1 may be in a range of from about 50 μm to about 200 μm. The third height H3 may be in a range of from about 15 μm to about 150 μm.

The adhesive member 400 may reinforce the space between the conductive members 110. For example, the adhesive member 400 may have a dam shape. The adhesive member 400 may include an epoxy resin, a UV resin, a polyurethane resin, a silicone resin, or a silica filler.

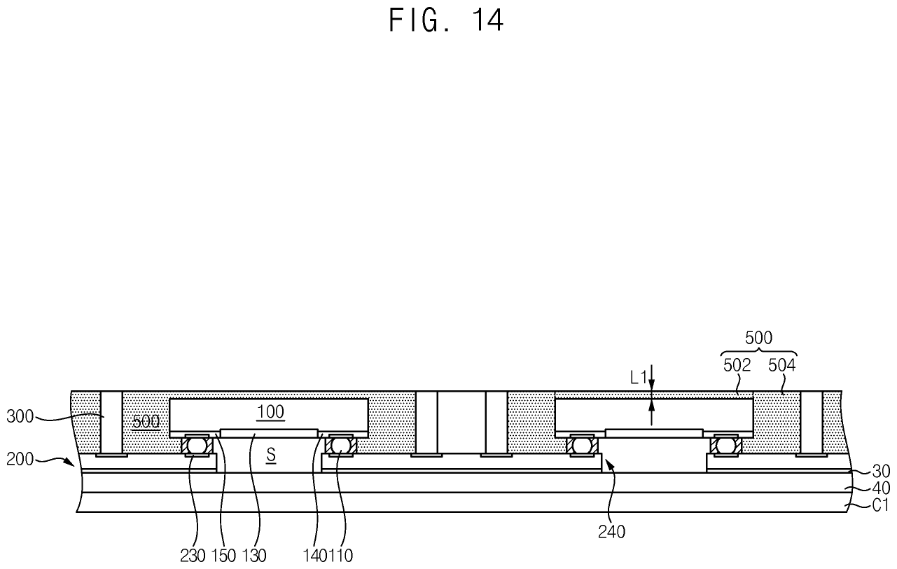

Referring to FIG. 14, a sealing member 500 may be formed to cover the image sensor chip 100, the first redistribution layer 200, the conductive structures 300, and the adhesive member 400 in an overmold structure.

The sealing member 500 may be formed to surround all of the image sensor chip 100, the first redistribution layer 200, the conductive structures 300, and the adhesive member 400. The sealing member 500 may include a first sealing portion 502 covering the upper surface 122 of the image sensor chip 100 and a second sealing portion 504 covering an outer surface of the image sensor chip 100. The sealing member 500 may be formed to surround the adhesive member 400 such that the sealed space S between the lens and the central opening 240 enclosed by the adhesive member 400 is maintained.

An upper surface of the sealing member 500 may be polished to be even to form the second redistribution layer 600 thereon. The upper surface of the sealing member 500 may be polished through a grinding process. In the grinding process, the sealing member 500 may be polished to expose an upper surface of the conductive structure 300 and to cover the upper surface of the image sensor chip 100.

After the grinding process, the first sealing portion 502 may be formed to have a first thickness L1 between the second redistribution layer 600 and the image sensor chip 100. For example, the first thickness L1 of the first sealing portion 502 may be in a range of from about 20 μm to about 200 μm.

For example, the sealing member 500 may include an epoxy mold compound (EMC).

Referring to FIGS. 15 and 16, the second redistribution layer 600 electrically connected to the conductive structures 300 may be formed on the sealing member 500.

A second bonding pad 630 may be formed on the sealing member 500. The second bonding pad 630 may be formed by forming a seed layer on a portion of the sealing member 500, patterning the seed layer, and performing an electrolytic plating process. For example, the second bonding pad may include aluminum (Al), copper (Cu), tin (Sn), nickel (Ni), gold (Au), platinum (Pt), or an alloy thereof.

After forming a second insulating layer 610a covering the second bonding pad 630 on the sealing member 500, a second opening exposing the second bonding pad 630 may be formed by patterning the second insulating layer 610a.

A second redistribution wiring 620 may be formed on the second insulating layer 610a to directly contact the second bonding pad 630 through the second openings.

After forming a third insulating layer 610b covering the second redistribution wirings 620 on the second insulating layer 610a, the third insulating layer 610b may be patterned to form third openings respectively exposing the second redistribution wirings 620.

A plurality of third bonding pads 640 directly contacted with the second redistribution wirings 620 may be formed on the third insulating layer 610b through the third openings.

A photoresist pattern having openings exposing a region of the third bonding pad 640 may be formed on the upper surface of the second redistribution layer 600, and an external connection member 650 may be formed on the third bonding pad 640.

Specifically, after the opening of the photoresist pattern is filled with a conductive material, the photoresist pattern may be removed and a reflow process may be performed to form the external connection member 650. For example, the external connection member 650 may be formed by a plating process. Alternatively, the external connection member 650 may be formed by a screen printing method, a deposition method, or the like. For example, the external connection member 650 may include a C4 bump.

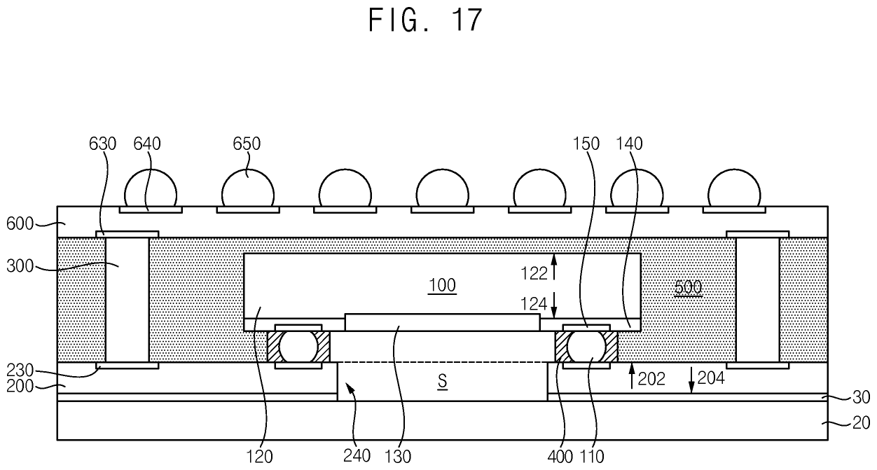

Referring to FIG. 17, the first and second redistribution layers 200, 600, the sealing member 500, and the glass may be cut through a sawing process. The semiconductor package 10 of FIG. 1 may be completed by cutting the first and second redistribution layers 200, 600, the sealing member 500, and the glass.

As described above, the semiconductor package 10 manufactured by the method of manufacturing the semiconductor package may be electrically connected to the first redistribution layer 200 through the conductive members 110, and may be electrically connected to the second redistribution layer 600 through the conductive structures 300. Since the semiconductor package 10 of the example embodiment does not include through silicon vias (TSVs), time and cost consumed in the process may be reduced.

In addition, since the adhesive member 400 may be formed to surround the conductive members 110 before the sealing member 500, in an example embodiment, the sealing member 500 may be not introduced between the image sensor chip 100 and the sealed space S, and may be formed to cover all of the image sensor chip 100, the first redistribution layer 200, the conductive structures 300, and the adhesive member 400. Since the sealing member 500 covers the image sensor chip 100, it is possible to prevent chip cracks and defects due to Cu contamination that may occur in the image sensor chip.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages of the present invention. Accordingly, all such modifications are intended to be included within the scope of example embodiments as defined in the claims.

What is claimed is:

1. A method of manufacturing a semiconductor package, comprising:
forming a first redistribution layer having an opening on a transparent plate, the first redistribution layer comprising first redistribution wirings;
forming a plurality of conductive structures that extend in a vertical direction on the first redistribution layer and are electrically connected to the first redistribution wirings;
providing an image sensor chip comprising a lens, and providing a plurality of conductive members spaced apart along a peripheral region of the lens;
disposing the image sensor chip on the first redistribution layer such that the lens faces the opening and the conductive members are electrically connected to the first redistribution wirings;
forming an adhesive member that extends along the peripheral region and surrounds the conductive members between the first redistribution layer and the image sensor chip;
forming a sealing member on the first redistribution layer to cover the image sensor chip, the conductive structures, and the adhesive member; and
forming a second redistribution layer comprising second redistribution wirings electrically connected to the conductive structures, on the sealing member.

2. The method of claim 1, wherein forming the second redistribution layer further comprises exposing upper surfaces of the conductive structures by grinding an upper surface of the sealing member.

3. The method of claim 1, wherein the sealing member comprises a first sealing portion that covers an upper surface of the image sensor chip and a second sealing portion that surrounds side surfaces of the conductive structures around the image sensor chip.

4. The method of claim 1, wherein the adhesive member comprises a first adhesive portion that surrounds the conductive member, and a second adhesive portion that fills a space between the conductive members.

5. The method of claim 1, wherein forming the adhesive member comprises forming the adhesive member to have a predetermined width and a predetermined height,
wherein the predetermined width is in a range of about 50 μm to about 200 μm, and
wherein the predetermined height is in a range of about 15 μm to about 150 m.

6. The method of claim 1, wherein the image sensor chip is a CMOS image sensor (CIS) chip.

7. The method of claim 1, wherein a space between the opening on the transparent plate and the lens is enclosed by the adhesive member.

8. The method of claim 1, wherein the conductive structure comprises at least one of nickel (Ni), antimony (Sb), bismuth (Bi), zinc (Zn), indium (In), palladium (Pd), platinum (Pt), aluminum (Al), copper (Cu), molybdenum (Mo), titanium (Ti), gold (Au), silver (Ag), chromium (Cr), and tin (Sn).

9. The method of claim 1, wherein the adhesive member comprises at least one of epoxy resin, UV resin, polyurethane resin, silicone resin, and silica filler.

10. The method of claim 1, wherein the sealing member comprises an epoxy mold compound (EMC).

11. A method of manufacturing a semiconductor package, comprising:
forming a first redistribution layer having an opening on a transparent plate, the first redistribution layer comprising first redistribution wirings;
forming a plurality of conductive structures that extend in a vertical direction on the first redistribution layer and are electrically connected to the first redistribution wirings;
providing a CMOS image sensor chip comprising a lens, and providing a plurality of conductive members spaced apart along a peripheral region of the lens;
disposing the CMOS image sensor chip on the first redistribution layer such that the lens faces the opening and the conductive members are electrically connected to the first redistribution wirings;
forming an adhesive member that extends along the peripheral region between the first redistribution layer and the CMOS image sensor chip to enclose the conductive members and seal a space between the lens and the opening on the transparent plate;
forming a sealing member on the first redistribution layer to cover the CMOS image sensor chip, the conductive structures, and the adhesive member; and
forming a second redistribution layer that has second redistribution wirings electrically connected to the conductive structures, on the sealing member.

12. The method of claim 11, wherein forming of the second redistribution layer further comprises exposing upper surfaces of the conductive structures by grinding an upper surface of the sealing member through a grinding process.

13. The method of claim 11, wherein the sealing member includes a first sealing portion that covers an upper surface of the CMOS image sensor chip and a second sealing portion that surrounds side surfaces of the conductive structures around the CMOS image sensor chip.

14. The method of claim 11, wherein the adhesive member comprises a first adhesive portion that surrounds the conductive member, and a second adhesive portion that fills a space between the conductive members.

15. The method of claim 11, wherein forming the adhesive member includes forming the adhesive member to have a predetermined width and a predetermined height,
wherein the predetermined width is in a range from about 50 μm to about 200 μm, and
wherein the predetermined height is in a range from about 15 μm to about 150 μm.

16. A semiconductor package, comprising:
a transparent plate configured to allow light to transmit therethrough;
a first redistribution layer disposed on the transparent plate, the first redistribution layer having an opening through which light may pass, the first redistribution layer comprising first redistribution wirings;
an image sensor chip comprising a lens, further comprising a plurality of conductive members in a peripheral region surrounding the lens, and wherein the image sensor chip is disposed on the first redistribution layer such that the conductive members are electrically connected to the first redistribution wirings, the lens facing the opening that such that light may be incident on the lens;
an adhesive member extending along the peripheral region between the first redistribution layer and the image sensor chip, the adhesive member surrounding the conductive members to enclose a space between the lens and the opening from an outside;
a sealing member provided on the first redistribution layer to cover the image sensor chip and the adhesive member;
a second redistribution layer provided on the sealing member, the second redistribution layer having second redistribution wirings; and
a plurality of conductive structures penetrating through the sealing member and electrically connecting the first redistribution wirings and the second redistribution wirings.

17. The semiconductor package of claim 16, wherein the sealing member includes a first sealing portion that covers an upper surface of the image sensor chip and a second sealing portion that surrounds side surfaces of the conductive structures around the image sensor chip.

18. The semiconductor package of claim 16, wherein the adhesive member includes a first adhesive portion that surrounds the conductive member and a second adhesive portion that fills a space between the conductive members.

19. The semiconductor package of claim 16, wherein the adhesive member having a predetermined width and a predetermined height,
the predetermined width is within a range of from about 50 μm to about 200 μm,
the predetermined height is within a range of from about 15 μm to about 150 μm.

20. The semiconductor package of claim 16, wherein a space between the opening and the lens is enclosed by the adhesive member.
